(19) United States
(12) Patent Application Publication
(10) Pub. No.: US 2012/0111391 A1
(43) Pub. Date: May 10, 2012

(54) Reconfigurable Photovoltaic Structure

(76) Inventors: Mohamed Zakaria Mohamed Ahmed SHAMSELDEIN, Waterloo (CA); Mehrdad Kazerani, Waterloo (CA); Magdy Salama, Kitchener (CA)

(21) Appl. No.: 13/354,876

(22) Filed: Jan. 20, 2012

Related U.S. Application Data
(63) Continuation of application No. PCT/CA2011/000809, filed on Jul. 13, 2011.
(60) Provisional application No. 61/365,223, filed on Jul. 16, 2010.

(51) Int. Cl. H01L 31/02; H01L 31/18

(52) U.S. Cl. 136/249; 438/6; 257/E31.113

(57) ABSTRACT

A photovoltaic structure is provided. The photovoltaic structure has photovoltaic elements that can be electrically connected to one another to reduce mismatch. The photovoltaic elements can be electrically connected based on sorting the photovoltaic elements by irradiance level, minimizing mismatch, or maximizing output power. Where sorting is used, the photovoltaic elements can be connected in a serpentine arrangement.

### PRIORITY CLAIM

This application is a continuation of PCT Patent Application No. PCT/CA2011/000809, filed Jul. 13, 2011 which claims priority from U.S. Provisional Patent Application No. 61/365,223 filed Jul. 16, 2010, both of which are incorporated herein by reference.

### FIELD OF THE INVENTION

The present invention relates generally to a reconfigurable photovoltaic structure.

### DESCRIPTION OF THE PRIOR ART

Increase in oil prices, depletion of fossil fuel reservoirs, energy security concerns and global warming have been the most important motives behind the use of renewable energy for power generation, including solar energy. Energy from solar can be generated using photovoltaic (PV) structures. PV structures are expected to play a major role in smart grids as a distributed generation or as a power plant.

The use of PV structures for power generation brings many challenges, one of which is partial shading loss. Partial shading loss occurs when a part of a PV structure is shaded by a shading source. These sources could be predictable sources such as nearby structures, trees and arrays or unpredictable sources such as clouds, dust and snow. For example, it has been shown that a neighbouring building, tree or passing clouds can cause a PV structure to have an annual loss up to 10%

A PV structure comprises a plurality of PV elements such as cells, modules, panels, arrays, farm fields and farms. Partial shading causes the output of even the unshaded parts of the PV structure to decrease since a partially shaded PV structure has a mismatch between its constituent PV elements. When the PV elements are connected in what is referred to as series-parallel connection, the mismatch in the I-V characteristics of the series PV elements causes reduction in the generated power and hot spots. A total-cross-tied connection can reduce the effect of mismatch by first connecting the elements in the same physical row in parallel and then connecting all the rows in series, forming one column. This style of connection reduces the overall effect of mismatch in the PV system but is still affected by partial shading loss.

Hot spots can also be eliminated using bypass diodes. However, these diodes create multiple power peaks which increase the complexity of the Maximum Power Point Tracking (MPPT). The increased complexity of MPPT may lead to an operation that is not optimized at the maximum power point. Thus, the power generated by a system could be reduced significantly. Bypass diodes, furthermore, do not solve the problem of reduction in generated power.

The effects of partial shading from neighbouring arrays could also be reduced by increasing the PV system farm area. However, partial shading losses from unpredictable sources are difficult to reduce.

Reconfigurable PV arrays have been proposed to increase the generated power under partial shading conditions. Some of these proposals require complex calculations that require extended periods to calculate. These solutions are not always ideal in real-time applications and are therefore not optimally reactive to unpredictable sources of partial shading.

Another challenge for PV structures is detection of faults for PV elements or PV structures. Fault detection can include short circuit, open circuit and performance reduction faults. Short circuit faults have many types such as string to ground, leakage current inside one string, leakage current between two strings and leakage current inside an element. Open circuit faults could result from an open circuit in the string or inside the element or increased contact resistance of the element. Performance reduction faults could be due to soiling, cell degradation or increased temperature.

Fault detection methods for PV farms can be performed by visual inspection, thermal imaging with infrared camera or by electrical measurements. Visual and thermal imaging methods require inspection by an experienced worker which can take a long time for large PV farms. Electrical measurements can be much faster and more accurate than visual inspection and thermal imaging.

One electrical method of fault detection measures the MPP voltage of the PV array to detect open circuit and short circuit faults. This method cannot discriminate between partial shading of the array or a fault inside the array and it cannot detect the faulty module.

Another electrical method of fault detection measures the array I-V characteristic and compares it with a simulated I-V characteristic. This method requires an accurate model for the PV array and accurate measurements of irradiance and temperature for each module. This method can detect the faulty array but cannot detect the faulty module.

Yet another electrical method of fault detection for open circuit faults only is Earth Capacitance Measurement (ECM). This method is based on the fact that the value of earth capacitance is independent of the irradiance level. Time Domain Reflectometry (TDR) is another method. In TDR, a signal is sent to the PV string and compared with the reflected signal. This comparison will give information about the type and location of fault. TDR is affected by installation circumstances such as wiring, modules types and mounting materials. This means that the characteristics of the string should be measured directly alter installation and after any change in string components or connections.

It is therefore an object of the present invention to obviate or mitigate the above disadvantages.

### SUMMARY OF THE INVENTION

In one aspect, a photovoltaic structure is provided, said photovoltaic structure characterized by a plurality of photovoltaic elements, said photovoltaic elements selectively electrically connectable to one another based on sorting said photovoltaic elements by a respective irradiance level.

The photovoltaic structure may be characterized in that it comprises m parallel circuits, wherein said photovoltaic elements are selectively electrically connectable to one another by: establishing a serpentine arrangement by connecting each one of a first in of said sorted photovoltaic elements to a respective one of said in parallel circuits and connecting each one of a second m of said sorted photovoltaic elements to said in parallel circuits in a reverse order to said first in; and repeating said serpentine arrangement for the remaining sorted photovoltaic elements.

In another aspect, a method of electrically connecting a plurality of photovoltaic elements in a photovoltaic structure is provided, said method characterized by: determining irradiance levels for said photovoltaic elements; sorting said photovoltaic elements by said irradiance levels; and electrically connecting said photovoltaic elements to one another based on said sorted irradiance levels.

The method, wherein said photovoltaic structure comprises m parallel circuits, may be characterized in that said photovoltaic elements are selectively electrically connectable to one another by: establishing a serpentine arrangement by connecting each one of a first m of said sorted photovoltaic elements to a respective one of said m parallel circuits and connecting each one of a second in of said sorted photovoltaic elements to said m parallel circuits in a reverse order to said first m; and repeating said serpentine arrangement for the remaining sorted photovoltaic elements.

In a further aspect, a photovoltaic structure is provided, said photovoltaic structure characterized by a plurality of photovoltaic elements, said photovoltaic elements selectively electrically connectable to one another based on determining a minimum mismatch between said parallel circuit.

In an additional aspect, a photovoltaic structure is provided, said photovoltaic structure characterized by a plurality of photovoltaic elements, said photovoltaic elements selectively electrically connectable to one another based on determining a maximum output power of said photovoltaic structure.

In yet another aspect, an irradiance level sensor for a photovoltaic element is provided, the irradiance level sensor comprising one or more imaging device operable to determine an irradiance pattern coupled to an irradiance level calibrator operable to correlate said irradiance pattern with an irradiance level for said photovoltaic element.

In a still further aspect, a method of detecting a fault in a total cross tied photovoltaic structure is provided, the method comprising: (a) monitoring the terminal voltage or terminal current of the photovoltaic structure; (b) monitoring the voltage of each of a plurality of rows of the photovoltaic structure; and (c) responsive to a transient in the terminal voltage or terminal current, determining that a fault exists in one or more of said plurality of rows having the lowest voltage.

### BRIEF DESCRIPTION OF THE DRAWINGS

The features of the invention will become more apparent in the following detailed description in which reference is made to the appended drawings wherein:

FIG. 1 is a block diagram of a portion of a PV structure;

FIG. 2 is a schematic representation of a further portion of the PV structure of FIG. 1;

FIG. 3 is a schematic representation of a further portion of the PV structure of FIG. 1;

FIG. 4 is a schematic representation of a further portion of the PV structure of FIG. 1;

FIG. 5 is a block diagram of a further portion of the PV structure of FIG. 1;

FIG. 6 is a schematic representation of an example of a total-cross-tied PV structure and a PV structure connected in accordance with the present invention;

FIG. 7 is a block diagram illustrating connections for a plurality of PV elements in a PV structure;

FIG. 8 is a flowchart of a method of configuring a PV structure;

FIG. 9 is a flowchart of a method of measuring irradiance levels of PV elements in a PV structure;

FIG. 10 is a flowchart further illustrating the method of FIG. 9;

FIG. 11 is a flowchart illustrating fault detection in a PV structure;

FIG. 12 is a flowchart showing an example of a merge sort;

FIG. 13 is a schematic representation of an equivalent circuit of a PV element;

FIG. 14 is a schematic representation of a PV structure illustrating irradiance levels of PV elements arranged on a PV structure under no partial shading;

FIG. 15 is a graphical illustration of a comparison of P-V characteristics of a series-parallel PV structure, series parallel with bypass diodes PV structure, total-cross-tied PV structure and a PV structure connected in accordance with the present invention for no partial shading;

FIG. 16 is a schematic representation of an example of a typical PV structure and a PV structure connected in accordance with the present invention based on a first partial shading condition;

FIG. 17 is a graphical illustration of a comparison of P-V characteristics of a series-parallel PV structure, series parallel with bypass diodes PV structure, total-cross-tied PV structure and a PV structure connected in accordance with the present invention for the first partial shading condition;

FIG. 18 is a schematic representation of an example of a typical PV structure and a PV structure connected in accordance with the present invention based on a second partial shading condition;

FIG. 19 is a graphical illustration of a comparison of P-V characteristics of a series-parallel PV structure, series parallel with bypass diodes PV structure, total-cross-tied PV structure and a PV structure connected in accordance with the present invention for the second partial shading condition;

FIG. 20 is a schematic representation of a PV structure illustrating a short circuit fault;

FIG. 21 is a graphical illustration of a comparison of P-V characteristics of a series-parallel PV structure, series parallel with bypass diodes PV structure, total-cross-tied PV structure and a PV structure connected in accordance with the present invention for the short circuit fault;

FIG. 22 is a schematic representation of a PV structure illustrating an open circuit fault;

FIG. 23 is a graphical illustration of a comparison of P-V characteristics of a series-parallel PV structure, series parallel with bypass diodes PV structure, total-cross-tied PV structure and a PV structure connected in accordance with the present invention for the open circuit fault;

FIG. 24 is a schematic representation of a single-pole m-throw rotary switch;

FIG. 25 is a schematic representation of an irradiance level sensor comprising an imaging device coupled to an irradiance level calibrator;

FIG. 26 is a schematic representation of a PV structure having a voltage sensor and current sensor;

FIG. 27 is a schematic representation of the PV structure shown previously in FIG. 26;

FIG. 28 is a graphical illustration of a current time response; and

FIG. 29 is a graphical illustration of a voltage time response.

### DETAILED DESCRIPTION OF THE INVENTION

The present invention provides a reconfigurable PV structure. The reconfigurable PV structure can be used to reduce mismatch. Mismatch can, for example, be caused by partial shading loss. The invention can reduce mismatch in the PV structure due to both predictable and unpredictable sources. It can also be used to locate or isolate faults in the PV structure and reduce the effects of these faults.

A PV structure as described herein comprises a plurality of PV elements. The PV elements could be PV cells, PV modules, PV panels, PV arrays, PV farm fields, PV farms, or any combination thereof.

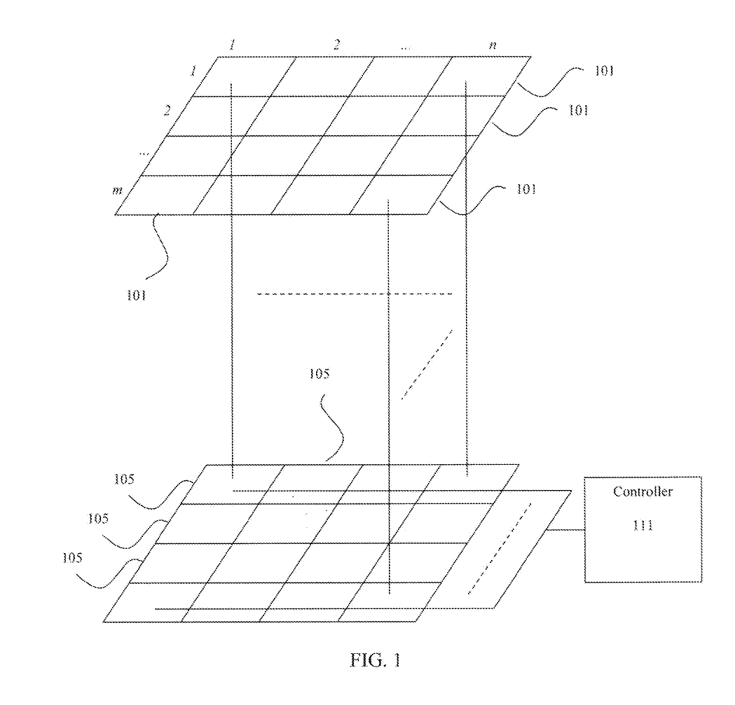

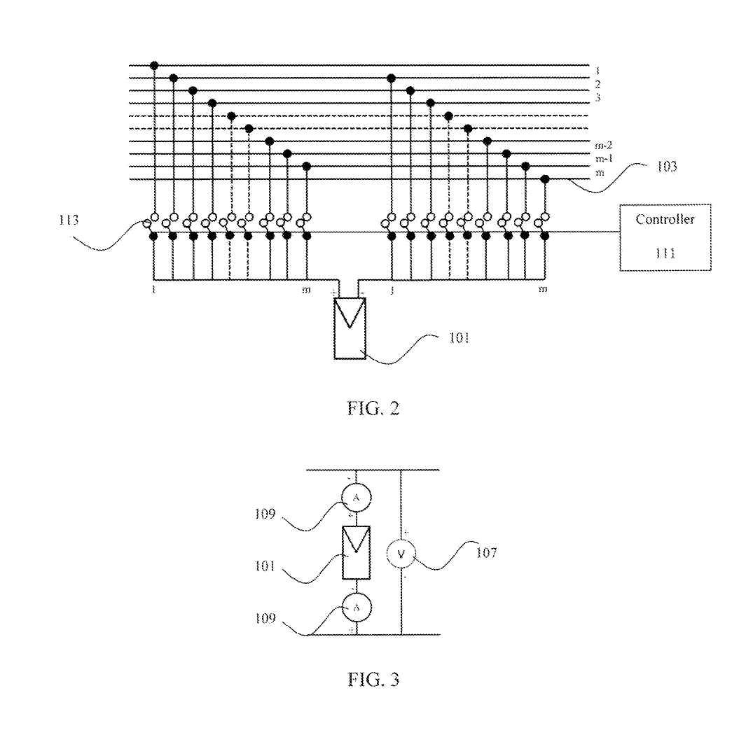

Referring therefore to FIGS. 1 to 4, a reconfigurable PV structure in accordance with the present invention comprises a plurality of PV elements 101 physically arranged in m rows and n columns. m+1 electrical conductors 103, such as wires or PCB traces for example, are provided for the m rows but it is not necessarily the case that PV elements physically arranged in a particular row are connected to the electrical conductors corresponding to that row.

In one aspect, the reconfigurable PV structure is operable to configure a circuit arrangement for the PV elements to reduce the effects of mismatch in the PV structure during a mismatch causing condition, such as a partial shading condition, for example. This mismatch may be based on different irradiance levels experienced by at least two of the PV elements. These irradiance levels may be observed, estimated or predicted.

In another aspect, the reconfigurable PV structure is operable to configure a circuit arrangement for the PV elements to reduce mismatch by maximizing the power generated by the PV structure, for example during a partial shading condition.

In another aspect, the reconfigurable PV structure is operable to configure a circuit arrangement for the PV elements to reduce mismatch by sorting the PV elements based on irradiance levels, for example during a partial shading condition, and arranging them in the circuit based on their position in a sorted list.

In another aspect, the reconfigurable PV structure is operable to configure a circuit arrangement for the PV elements to locate one or more faults in the PV structure and to minimize the effects of these faults.

In one aspect, each PV element is linked to one of a plurality of irradiance level sensors 105 that senses the irradiance level of that PV element. The irradiance level sensors could be substituted with voltage sensors 107 and current sensors 109 operable to provide an estimate of the irradiance levels for each PV element based on PV model equations. A PV structure having both reconfigurable and non-reconfigurable PV elements has m(n_{R}+1) irradiance level sensors 105 or m(n_{R}+2) voltage sensors 107 and current sensors 109 with each reconfigurable PV element having one current sensor 109 and each row having a voltage sensor 107, where n_{R} is the number of columns having reconfigurable PV elements. Each row having non-reconfigurable PV elements may have one irradiance level sensor 105 for the non-reconfigurable part, or two voltage sensors 107 and current sensors 109. Preferably, to enable the reconfigurable PV structure to reduce the effects of faults, each PV element has two current sensors 109 so that the PV structure has m(2n_{R}+3) sensors.

A PV structure having only reconfigurable PV elements preferably has mn_{R} irradiance level sensors 105 or m(n_{R}+1) voltage sensors 107 and current sensors 109.

Referring now to FIG. 25 in another aspect, irradiance level sensors 105 may be implemented by one or more imaging device 2502, operable to determine an irradiance pattern, coupled to an irradiance level calibrator.

The imaging device 2502 may, for example, comprise one or more camera 2506 communicatively coupled to an image processing engine 2508. The cameras could be visible light cameras. The cameras 2506 may be operable to capture images of the PV structure at a sufficient resolution such that, when they are communicated to the image processing engine 2508, the image processing engine 2508 can apply one or more image processing algorithms, such as a pattern recognition algorithm, to the images to determine an irradiance pattern corresponding to the shading of each PV element.

The imaging device 2502 may, in another example, be one or more infrared camera 2510 that is operable to determine an irradiance pattern corresponding to the temperature of the various PV elements.

The irradiance level calibrator may comprise a historical irradiance level table 2512 based on historical irradiance levels observed by the imaging device having obtained a shading or temperature of a PV element, as the case may be. The historical irradiance level table 2512 may correlate particular amounts of shading and/or particular PV element temperatures, as the case may be, with particular irradiances. Thus, the irradiance level calibrator 2504 can be used in conjunction with the imaging device to determine the most likely irradiance level of each PV element based on the observance of the imaging device.

The irradiance level sensors 105 are further linked to a controller 111. The irradiance level sensors 105 communicate the irradiance levels of each of the PV elements 101 to the controller 111. The controller 111 could be a programmable logic controller, microcontroller or microprocessor.

The controller 111 controls a plurality of switches 113 for a subset of PV elements 101 that can be referred to as reconfigurable PV elements 115. The remaining PV elements can be referred to as non-reconfigurable PV elements 119. Each reconfigurable PV element 115 preferably has m switches 115 at one node and in switches 117 at another node.

The reconfigurable PV elements 115 can be selectively connected to two of the conductors by closing one of switches 115 and one of switches 117. The switches 115, 117 that are to be closed connect the reconfigurable PV element 115 to two sequential conductors (for example, connected to the first and second conductors defining parallel circuit 1). In this way, when all the reconfigurable PV elements 115 are connected to the circuit, a plurality of parallel circuits 1, 2, m are defined by the PV elements connected between the electrical conductors.

Thus, each reconfigurable PV element 115 can be connected in a parallel circuit that is different from the parallel circuit in which another PV element from the same row is connected. Each reconfigurable PV element 115 is connectable to at least two of the parallel circuits and preferably is connectable to any of the parallel circuits.

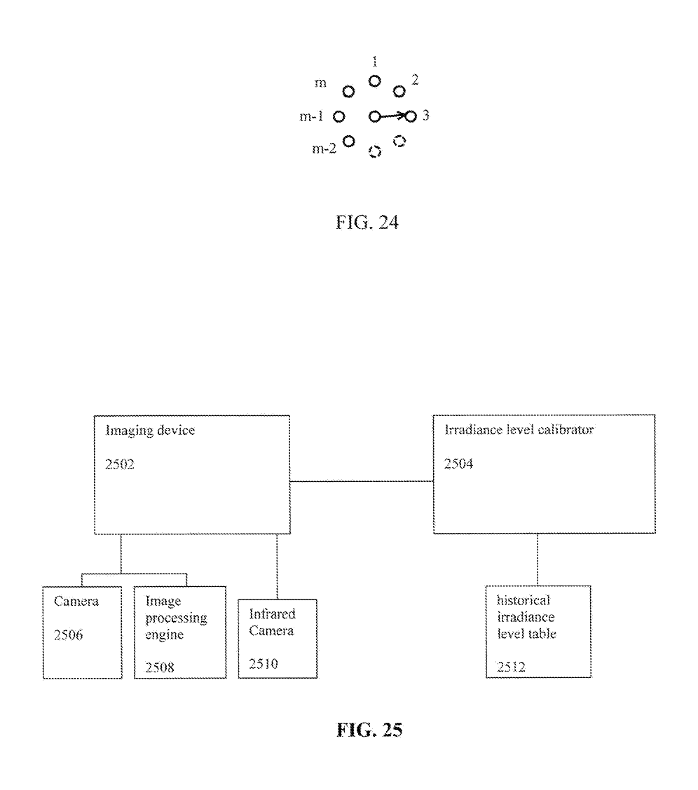

Preferably, each PV element has 2m single-pole, single-throw switches to be able to be connected to any parallel circuit. Preferably, the PV structure has 2m²n_{R} single-pole, single-throw switches so that each PV element is a reconfigurable element that can connect to any parallel circuit. Alternatively, as shown in FIG. 24, 2mn_{R} single-pole m-throw rotary switches could be used. The switches could be transistors, relays or circuit breakers according to the required current and voltage ratings.

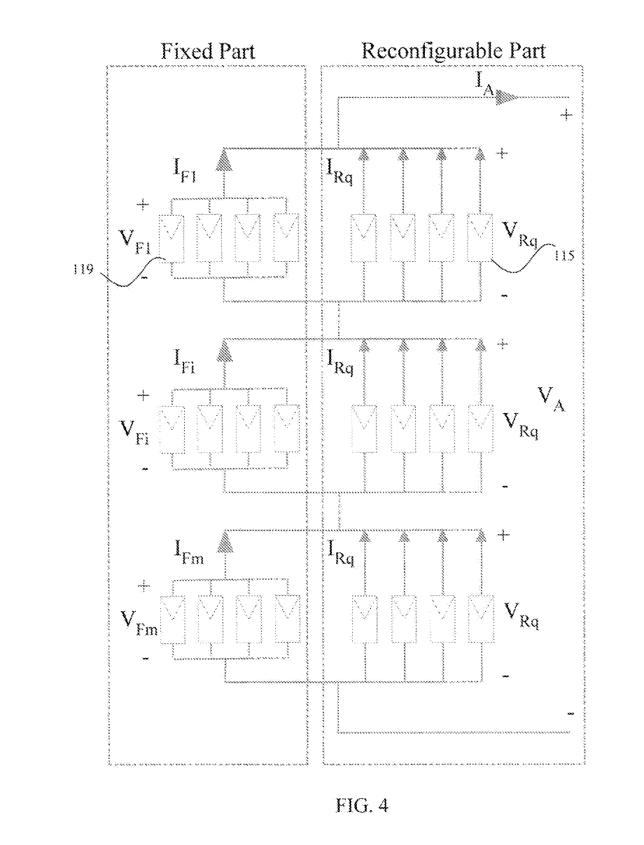

Referring now to FIG. 4, each non-reconfigurable PV element 119 is fixedly connected between two sequential conductors, similar to a total-cross-tied connection.

The subset of PV elements that are reconfigurable PV elements 115 can be as few as two PV elements and as many as all the PV elements. Preferably, there are at least m reconfigurable PV elements 115.

The following description assumes that a PV structure comprises only reconfigurable PV elements and, therefore, uses the term “PV element” to refer to the reconfigurable PV elements, except where otherwise stated.

Referring now to FIG. 5, the controller 111 implements a mismatch reduction engine 123 and may further be linked to a PV structure parameter table 125. The PV structure parameter table 125 comprises parameters for the PV structure, including, for example, a reference irradiance level, element short circuit current at the reference irradiance level, reverse bias diode saturation current, number of series cells in the element, element series resistance, element thermal voltage, and element parallel resistance.

The controller 111 may further be linked to a storage medium 127 that is operable to temporarily or permanently store electronic data corresponding to irradiance levels, voltage measurements, current measurements, switch status, variables as described below, fault status and other relevant information. The storage medium 127 can be implemented by a memory, such as non-volatile memory such as a flash memory or a magnetic disk, or volatile memory, such as a Random Access Memory (RAM), for example.

The mismatch reduction engine is operable to configure a circuit arrangement for the reconfigurable PV elements to reduce mismatch based on irradiance levels collected by the irradiance level sensors for all the PV elements in the PV structure. The reduction in mismatch can be observed relative to a total cross tied configuration.

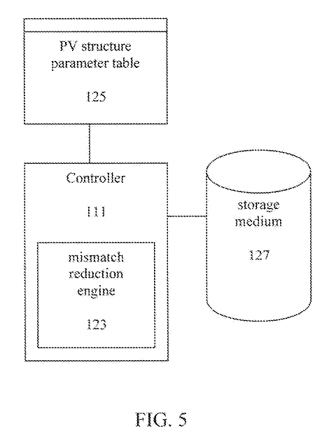

Referring therefore to FIG. 6a, a typical total-cross-tied PV structure is shown in accordance with its circuit arrangement. The physical location of each PV element in the PV structure is denoted by a reference numeral that is its row number followed by column number (i.e., PV element 13 is physically located at row 1, column 3 of the PV structure). A typical total-cross-tied PV structure connects each PV element in a particular row in parallel. Each of these parallel circuits are then connected together in series, as shown.

In one aspect, it has been found that based on observation or prediction of sources of partial shading loss, partial shading loss can be reduced by connecting the PV elements to one another in accordance with the fact that adjacent PV elements are more likely to be shaded simultaneously than elements placed further from one another. It has been found that it is possible to reduce the overall mismatch between the PV elements during partial shading to increase the generated power of the PV system by connecting at least a subset of the PV elements from different rows in parallel and then connecting the rows in series to form one column. Connecting the shaded PV elements in different parallel circuits may result in more uniform distribution of irradiance levels that may reduce partial shading losses. The resulting arrangement may also have fewer power peaks than are created using bypass diodes. The resulting arrangement can be considered as a modification to the total-cross-tied connection.

Referring therefore to FIG. 6b, an example of a PV structure having a circuit arrangement in accordance with the present invention is shown. Again, the physical location of each PV element in the PV structure is denoted by a reference numeral that is its row number followed by its column number. In this example, one parallel circuit is comprised of PV elements 11, 42, 23 and 54 from (1, 1), (4, 2), (2, 3) and (5, 4), respectively; another parallel circuit is comprised of PV elements 21, 52, 33 and 64 from (2, 1), (5, 2), (3, 3) and (6, 4), respectively; another parallel circuit is comprised of PV elements 31, 62, 13 and 44 from (3, 1), (6, 2), (1, 3) and (4, 4), respectively; another parallel circuit is comprised of PV elements 41, 12, 53 and 24 from (4, 1), (1, 2), (5, 3) and (2, 4), respectively; another parallel circuit is comprised of PV elements 51, 22, 62 and 34 from (5, 1), (2, 2), (6, 3) and (3, 4), respectively; and another parallel circuit is comprised of PV elements 61, 32, 43 and 14 from (6, 1), (3, 2), (4, 3) and (1, 4), respectively.

In accordance with the present invention, the circuit arrangement does not require all PV elements from any particular row to be connected in parallel. Rather, in accordance with the system and method described herein, at least one of the PV elements can be connected in parallel with at least one PV element from a different physical row in the PV structure. Thus, at least two PV elements from one of the physical rows can be connected in different parallel circuits. These two PV elements could, for example, be adjacent PV elements from a particular row. It should be understood that the PV structure shown is one example only, and that different circuit arrangements may be provided based on particular irradiance levels.

The mismatch reduction engine 123 executes a power maximizing algorithm, a mismatch reducing algorithm or an irradiance level sorting algorithm for a particular PV structure to configure a circuit arrangement for the reconfigurable PV elements to reduce partial shading loss

The power maximizing algorithm considers the power production for a particular PV structure connected in a total-cross-tied connection. For example, for a m×n total-cross-tied structure where m is the number of rows and n is the number of columns, the mismatch reduction engine is operable to determine an optimal set of connections, based on switch arrangements, for the PV structure that maximizes power production under a partial shading condition.

Referring again to FIG. 4, the maximization of power production can therefore be formulated by:

Maximize P_{A}=V_{A}I_{A} (1),

where P_{A} is array power, V_{A} is the array voltage and I_{A} is the array current.

The mismatch reduction engine considers a number of circuit constraints for providing the connection matrix. These include Kirchhoff's Current Law and Kirchhoff's Voltage Law at each time segment, which can be formulated as follows:

$${I}_{A} = {I}_{Fi} + {\sum }_{j = 1}^{{n}_{R}} {\sum }_{q = 1}^{{mn}_{R}} {I}_{Rq} {y}_{ijq} ∀ i , \qquad ( 2 )$$

where I_{Fi} is the array non-reconfigurable part current at row i, i is the row index, j is the reconfigurable column index, q is the reconfigurable element index, n_{R} is the number of reconfigurable columns, m is the number of rows, I_{Rq} is the reconfigurable element q current, and y_{ijq} is a binary variable taking the value 1 when element q is at position (i,j) and 0 otherwise;

$${V}_{Fi} = {\sum }_{q = 1}^{{mn}_{R}} {V}_{Rq} {y}_{ijq} ∀ i , j , \qquad ( 3 )$$

where V_{Fi} is the array non-reconfigurable part voltage at row i, and V_{Rq} is the reconfigurable element q voltage; and

$${V}_{A} = \text{?} {V}_{Fi} . \\ \text{?} \text{indicates text missing or illegible when filed} \qquad ( 4 )$$

The I-V characteristics for each reconfigurable PV element can be described by:

$${IRR}_{q} \frac{{I}_{sc}}{G} - {I}_{0} ( e \text{?} - 1 ) - \text{?} - {I}_{Rq} = 0 ∀ q \\ \text{?} \text{indicates text missing or illegible when filed} \qquad ( 5 )$$

where IRR_{q} is the reconfigurable element q irradiance level, G is a reference irradiance level, I_{sc}, is the element short circuit current at the reference irradiance level G, Iₒ is the reverse bias diode saturation current, Nₛ is the number of series cells in the element (which may be 1 if the element is a cell, or more than one if the element is a module), Rₛ is the element series resistance, V_{T} is the element thermal voltage and Rₚ is the element parallel resistance.

The I-V characteristics for each non-reconfigurable PV part in each row can be described by:

$${IRR}_{i} \frac{{I}_{sc}}{G} - {n}_{F} {I}_{0} ( e \text{?} - 1 ) - {n}_{F} \text{?} - {I}_{Fi} = 0 ∀ i . \\ \text{?} \text{indicates text missing or illegible when filed} \qquad ( 6 )$$

where IRRᵢ is the array fixed part irradiance level at row i and n_{F} is the number of fixed columns.

Other formulas to describe I-V characteristics of the elements could also be used.

The mismatch reduction engine also considers logical constraints, including:

$$\begin{matrix} {\sum }_{i = 1}^{m} {\sum }_{j = 1}^{{n}_{R}} {y}_{ijq} = 1 ∀ q ; \\ and & ( 7 ) \\ \text{?} = 1 ∀ i , j , \\ \text{?} \text{indicates text missing or illegible when filed} & ( 8 )\end{matrix}$$

which ensure that each reconfigurable PV element is used once and only once in the PV structure and that each position in the PV structure has one and only one PV element.

If the reconfigurable PV structure comprises reconfigurable PV elements only, and has no non-reconfigurable PV elements, then I_{Fi} in (2) can be set to zero, (6) can be omitted, and (2) can be rewritten as:

$${I}_{A} = {\sum }_{j = 1}^{n} {\sum }_{q = 1}^{mn} \text{?} ∀ i . \\ \text{?} \text{indicates text missing or illegible when filed} \qquad ( 9 )$$

By determining the array power for each possible configuration of PV elements in the PV structure, the mismatch reduction engine can therefore configure a circuit arrangement for the reconfigurable PV elements to reduce mismatch.

The mismatch reduction engine can also implement a mismatch reduction algorithm. The objective of maximizing the output generated power from the PV structure under non-uniform irradiance (e.g., partial shading) conditions can also be achieved by reconfiguring the PV structure in such a way that all the parallel circuits will have equal or as close to equal as possible total irradiance level. This provides a column of PV elements with uniform or approximately uniform irradiance level, which will give the maximum possible power for these irradiance levels, since all the PV elements will operate as close as possible to their MPPs. This will insure the least possible mismatch between PV elements. The mismatch reduction algorithm can determine a minimum mismatch index (MI), where the MI may correspond to the sum of the squares of differences between each row's total irradiance levels, which can be formulated as follows:

$$Minimize ( MI = {\text{?} [ \frac{\text{?}}{G} + {\sum }_{q = 1}^{{mn}_{R}} \frac{{IRR}_{q} {y}_{iq}}{G} - \frac{{IRR}_{l}}{G} - {\sum }_{q = 1}^{{mn}_{R}} \frac{{IRR}_{q} {y}_{lq}}{G} ]}^{2} ) \text{?} \\ \text{?} \text{indicates text missing or illegible when filed} \qquad ( 10 )$$

where MI is the mismatch index, l is the row index, y_{iq} is a binary variable taking the value 1 when element q is at row i and 0 otherwise, and y_{iq} is a binary variable taking the value 1 when element q is at row l and 0 otherwise. A smaller MI represents a more uniform irradiance level distribution among the rows, which reduces mismatch by, for example, partial shading loss.

The mismatch reduction engine is subject to a number of constraints in determining the minimum MI, including:

$$\begin{matrix}{\sum }_{i = 1}^{m} {y}_{iq} = 1 ∀ q ; \\ and & ( 11 ) \\ {\sum }_{q = 1}^{{mn}_{R}} {y}_{iq} = {n}_{R} ∀ i . & ( 12 )\end{matrix}$$

These constraints ensure that all the reconfigurable PV elements are used and that each row has exactly n_{R} elements respectively.

Alternatively, the reconfigurable PV structure may comprise rows having unequal numbers of elements if the constraint of equation (12) is relaxed. Also, the constraint of equation (12) can be changed as in equation (13) to limit the number of elements per row to be less than or equal to a certain number n_{Rmax}.

$${\sum }_{q = 1}^{mn} {y}_{iq} \leq {n}_{Rmax} ∀ i , \text{?} \\ \text{?} \text{indicates text missing or illegible when filed} \qquad ( 13 )$$

If the reconfigurable PV structure comprises reconfigurable PV elements only, and has no non-reconfigurable PV elements, then IRRᵢ and IRRₗ in (10) can be set to zero, and (13) can be rewritten as:

$$Minimize ( MI = {\sum }_{i = 1}^{m} {\sum }_{l = 1}^{m} {\text{?} [ {\sum }_{q = 1}^{{mn}_{R}} \frac{{IRR}_{q} {y}_{iq}}{G} - {\sum }_{q = 1}^{{mn}_{R}} \frac{{IRR}_{q} {y}_{lq}}{G} ]}^{2} ) \text{?} \\ \text{?} \text{indicates text missing or illegible when filed} \qquad ( 13 )$$

The mismatch reduction algorithm has fewer variables and constraints than the power maximizing algorithm, and it does not require any prior knowledge of the PV structure parameters. By determining the mismatch in the PV structure for each possible configuration of PV elements in the PV structure, the mismatch reduction engine can therefore configure a circuit arrangement for the reconfigurable PV elements that minimizes mismatch.

The power maximization algorithm and mismatch reduction algorithm may be characterized as Mixed Integer Non-Linear Programming (MINLP) algorithms. MINLP can be solved using Branch and Bound (BB) or heuristic algorithms. BB can require excessive time and computer memory for large problems (such as for large PV structures), which may not be suitable to provide real time reconfiguration unless significant processing power is provided.

Thus, the mismatch reduction engine can also implement an irradiance level sorting algorithm. By sorting the PV elements based on irradiance level, the PV elements can be connected in the PV structure to provide parallel circuits that have equal or as close to equal as possible total irradiance level. The irradiance level sorting algorithm may provide substantially similar effectiveness to reduce mismatch with less processing than may be required for the power maximization algorithm and mismatch reduction algorithm.

The irradiance level sorting algorithm may be a heuristic algorithm that could be based on a modification to the Bin Packing Problem (BPP). BPP has objects with different volumes that must be packed in a finite number of bins of constant capacity in such a way that the number of bins used is minimized. The irradiance level sorting algorithm, conversely, may represent each parallel circuit as a bin, and the irradiance levels as the objects to be packed. The objects (irradiance levels) can then be packed in such a way that all bins (parallel circuits) will have equal or close to equal capacity (total irradiance level). This differs from BPP in that the capacities of the bins (rows) are not known in advance and all bins (rows) must be used.

One approach to solve the BPP is First Fit (FF) which places the object (irradiance level) in the first bin (parallel circuit) it fits and if it does not tit into a bin then a new bin is started. First Fit Decreasing (FFD) approach is like FF but the objects are sorted in descending order before applying FF. Another approach is Best Fit (BF) which places the objects in the bin with the smallest gap left over. Best Fit Decreasing (BFD) is like BF with sorting the objects in descending order before applying BF. These approaches require a priori knowledge of the capacity (total irradiance level) of the bin (row) which is not known for a reconfigurable PV structure.

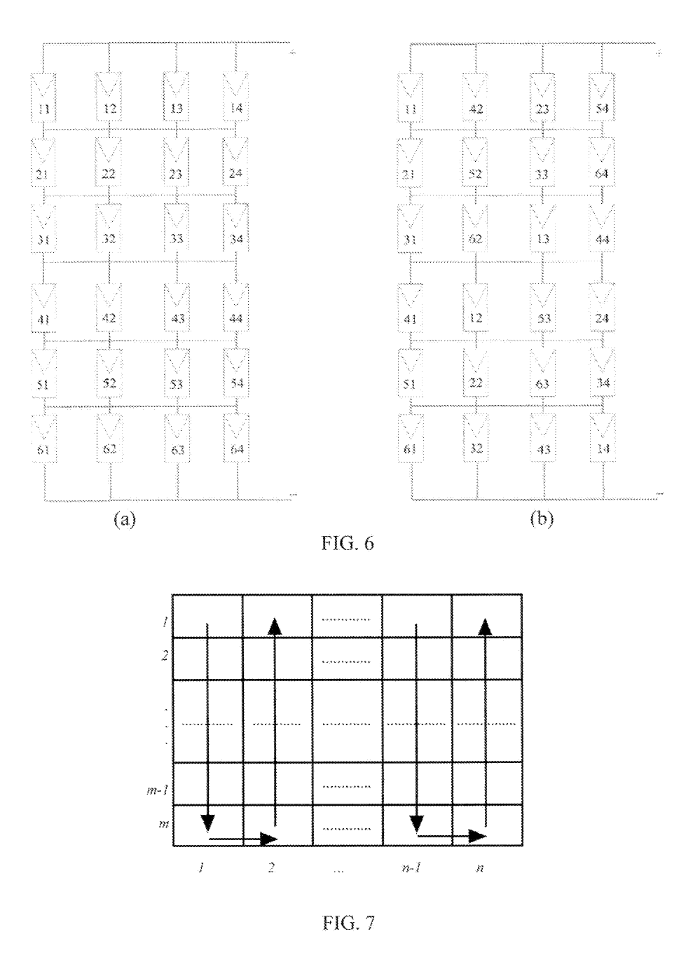

Referring now to FIG. 7, the mismatch reduction engine can sort all the PV elements based on irradiance levels in descending order (or in ascending order, which would provide a similar overall result), and then connect the PV elements among the parallel circuits. A preferable method of connecting the PV elements is a serpentine arrangement, which sequentially places the first m PV elements into the m parallel circuits, one PV element to one circuit. The next m parallel elements can then be connected in the reverse order into the m parallel circuits, and so on. In FIG. 7, the direction of arrows shows the connection of the descending order of the PV elements into the m parallel circuits.

Similarly, assuming one or more of the PV elements are non-reconfigurable, then the highest irradiance reconfigurable PV element can be connected to the lowest irradiance PV non-reconfigurable row, and so on. For example, for a PV structure in which one or more of the PV elements are non-reconfigurable, the irradiance levels of each of the non-reconfigurable rows are measured and then these non-reconfigurable rows are sorted in descending order (or in ascending order, which would provide a similar overall result). Next, the reconfigurable PV elements can be connected to the non-reconfigurable rows using the serpentine arrangement described above.

Referring now to FIG. 8, a flowchart is provided in accordance with the irradiance level sorting algorithm. Assuming that voltage and current sensors are used to determine irradiance levels, the mismatch reduction engine first measures voltage and current 801 for each of the PV elements. The mismatch reduction engine then conducts fault detection 803 to detect whether there is a fault in any of the PV elements and can disconnect these PV elements. For those PV elements for which there is no fault, the mismatch reduction engine determines irradiance levels for each PV element 805.

If irradiance level sensors are provided rather than voltage and current sensors, then 801 and 805 can be replaced by obtaining the irradiance levels for each sensor. In this case, fault detection 803 can be skipped.

Once all the irradiance levels are determined 805 or obtained, the PV elements can be sorted by their irradiance levels 807. The sorted list can be stored temporarily or permanently to a storage medium.

The sorted list of PV elements can be compared 809 to the previously sorted list that is stored on the storage medium. If the sorted list has not chanced, then it can be assumed that the PV structure is optimally configured and there is no switching required. The irradiance levels can be determined in another iteration from 801.

If the sorted list has changed, then the mismatch reduction engine can determine which signals must be switched by implementing a switching signal minimization algorithm 811.

The mismatch reduction engine can then switch the switches for the required PV elements 813 to configure the PV structure using, for example, the serpentine arrangement previously described.

Referring again to FIG. 3, a circuit to measure voltage and current for each PV element is shown. A voltage sensor 107 is connected in parallel with the PV element at position [row i, column j] to measure V(i,j) and current sensors 109 are connected in series with the PV element, one at its anode to measure up current I(i,j,u) and another at its cathode to measure down current I(i,j,d). These measurements can repeated at a particular delay interval in order to avoid measurement errors and rapid variation of irradiance levels. Again, only one current measurement would be needed if fault detection is not required.

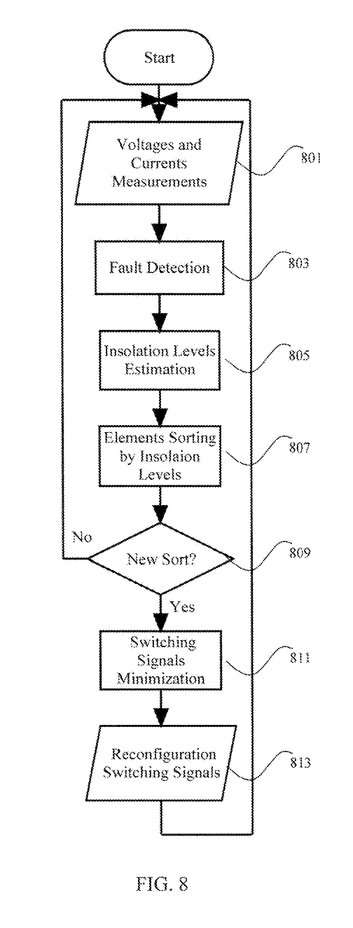

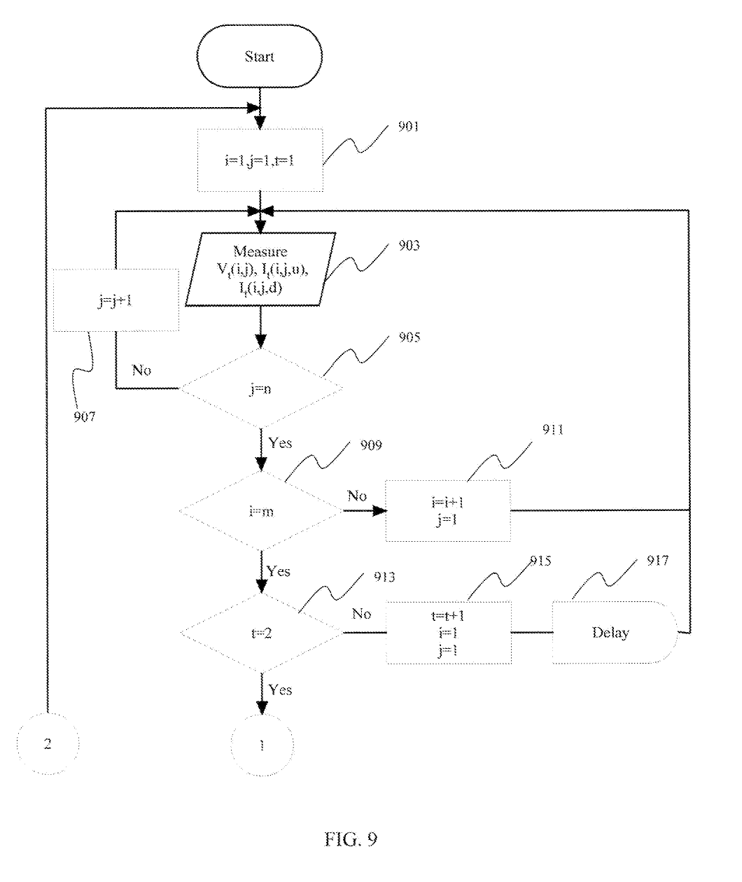

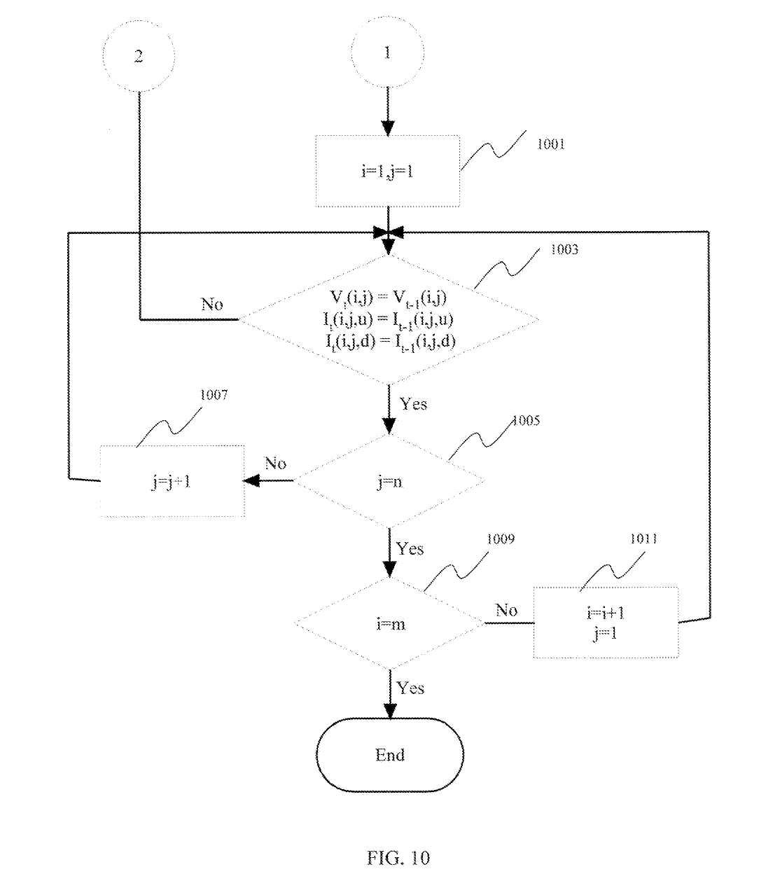

Referring now to FIGS. 9 and 10, a method for measuring the voltage and currents of each PV element is provided. Initially, the mismatch reduction engine sets i (the row index), j (the column index) and t (a time index) to one 901. The time index may be provided to enable the mismatch reduction engine to avoid reconfiguring the PV structure based on rapidly varying irradiance levels.

The mismatch reduction engine obtains, by the voltage and current sensors, V(i,j), I(i,j,u) and I(i,j,d) for the particular PV element located at (i,j) 903. The mismatch reduction engine then determines whether the column index j has reached the total number of columns n 905, and, if not, increments the column index j 907 and repeats steps 903 and 905.

Once j=n, the mismatch reduction engine then determines whether the row index has reached the total number of rows m 909. If not, at 911 the mismatch reduction engine increments the row index i and sets the column index j back to 1 and repeats steps 903 to 909.

Once i=m, the mismatch reduction engine determines at 913 whether the time index t has reached 2. If not, at 915 the mismatch reduction engine increments the time index t and sets both the column index j and the row index i back to 1. The mismatch reduction engine then delays 917 and repeats steps 901 to 913.

The mismatch reduction engine has, at this point, obtained V(i,j), I(i,j,u) and I(i,j,d) for all PV elements at time t=1 and t=2.

At 1001, the mismatch reduction engine sets the row index i and column index j back to 1. At 1003, if the voltage and currents obtained for the PV element in 903 are different from those for the same PV element at the previous t in 903, the mismatch reduction engine restarts the method at 901, since this indicates there is still some rapid variation in the irradiance level. In this regard, a person skilled in the art will appreciate that the delay in 917 is to be set accordingly.

If the measurements of voltage and currents are the same over successive measurements, there can be confidence in the accuracy of the measurements.

At 1005, the mismatch reduction engine determines whether the column index j has reached the total number of columns n. If not, j is incremented 1007, and the mismatch reduction engine repeats steps 1003 and 1005.

Once the column index j has reached the total number of columns n, the mismatch reduction engine determines at 1009 whether the row number i has reached the total number of rows m. If not, at 1011 the row index i is incremented, the column index j is set to 1 and the mismatch reduction engine repeats steps 1003 to 1009.

Once the row index i has reached the total number of rows m, the method is complete. At this point, the voltage and current measurements for all PV elements have been obtained.

Once the voltage and currents for each PV element are obtained, fault detection can be conducted.

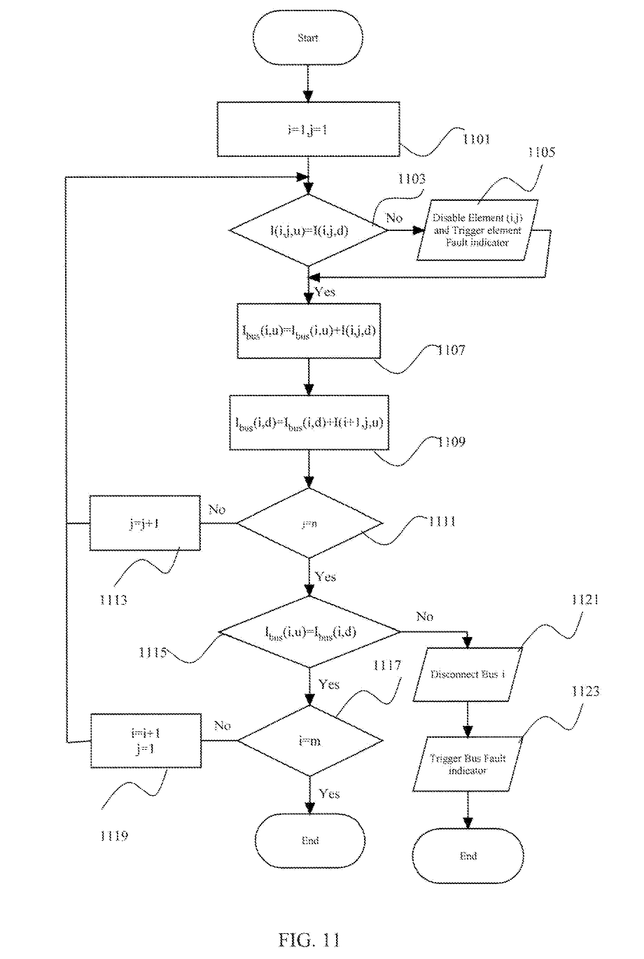

Referring therefore to FIG. 11, one method of detecting faults is provided. Fault detection can include short circuit, open circuit and performance reduction faults. Short circuit faults have many types such as string to ground, leakage current inside one string, leakage current between two strings and leakage current inside an element. Open circuit faults could result from an open circuit in the string or inside the element or increased contact resistance of the element. Performance reduction faults could be due to soiling, cell degradation or increased temperature.

Short circuit faults for a particular PV element may be detected by differential protection, which can be determined by comparing the PV element's up current I(i,j,u) with its down current, l(i,j,d).

Bus faults may also be detected. Bus faults may, for example, comprise a fault relating to any one or more of the electrical conductors (busses) that bridge the various parallel circuits. A bus may have an earth fault (short circuit to the earth or to the body of the PV structure) which could damage one or more of the PV elements connected to it. The bus may be a solid conductor material, a wire, a cable, etc. Bus faults can be determined by comparing the bus' up current l_{bus}(l,u) with its down current l_{bus}(l,d)

The mismatch reduction engine sets i and j to one 1101. The mismatch reduction engine compares the up current to the down current for the PV element at (i,j) 1103. If the up current and the down current are not equal, the PV element has a fault and the mismatch reduction engine directs the switches for that PV element to disconnect the PV element from the conductors for the rows 1105.

Once the PV elements are disconnected, or if the up current is equal to the down current, the bus up current is calculated. Based on Kirchoff's Current Law, the bus up current is equal to sum of all down currents for PV elements in that parallel circuit before that bus. Similarly, the bus down current is equal to the sum of all up currents of PV elements in the following parallel circuit.

Thus, at 1107 the parallel circuit up current I_{bus}(I,u) is incremented by the down current for the PV element at (i,j). For the parallel circuit down current, at 1109 it is incremented by the up current for the PV element at (i+1,j).

The mismatch reduction engine determines at 1111 whether the column index j has reached the total number of columns n. If not, at 1113 j is incremented, and then steps 1103 to 1111 are repeated.

Once the column index j has reached the total number of columns n, the parallel circuit up current is compared to the parallel circuit down current 1115. If the comparison of parallel circuit up current to parallel circuit down current gives equal values, there is no parallel circuit fault. The mismatch reduction engine determines at 1117 whether the row index i has reached the total number of rows m. If so, fault detection is complete. If not, at 1119 i is incremented, the column index j is set to 1, and then steps 1103 to 1117 are repeated

If the comparison at 115 gives non-equal current values, then there is a short circuit fault and the mismatch reduction engine can disconnect the faulty parallel circuit 1121 by opening the switches corresponding to all PV elements for that parallel circuit, which can be maintained until the parallel circuit is repaired. The PV structure can be reconfigured so that the previous parallel circuit is connected in series to following parallel circuit, essentially bypassing the faulty parallel circuit. Correspondingly, a parallel circuit fault indicator may be provided by storing a value to the storage medium 1123 indicating the particular fault, which can be inspected by a service person.

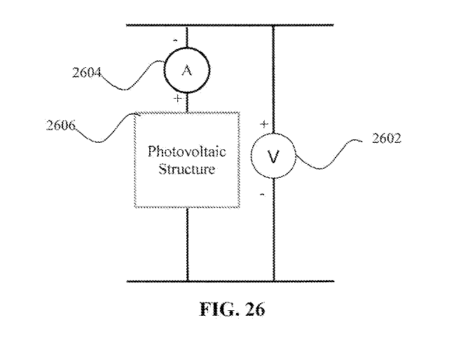

In another aspect, the mismatch reduction engine can apply fault detection with high security (i.e., low false positive fault detection) and discrimination (high accuracy of detecting the fault condition). Referring now to FIG. 26, one or both of a voltage sensor 2602 and a current sensor 2604 may be provided for the PV structure 2606 to measure the structure voltage (terminal voltage) and/or structure current (terminal current), respectively. The structure voltage and/or current can be provided to the mismatch reduction engine, which applies signal processing techniques to the time and/or frequency response of the structure voltage and/or current to determine the occurrence of a fault condition. The signal processing techniques may include Fourier Transform or wavelet transform for fault detection.

The signal processing techniques are implemented on the basis that the phenomenon of partial shading is slower than the occurrence of faults. Faults usually happen in a very short time while partial shading happens in a longer time, thus the transient response of the current and voltage will differ under a fault as opposed to partial shading.

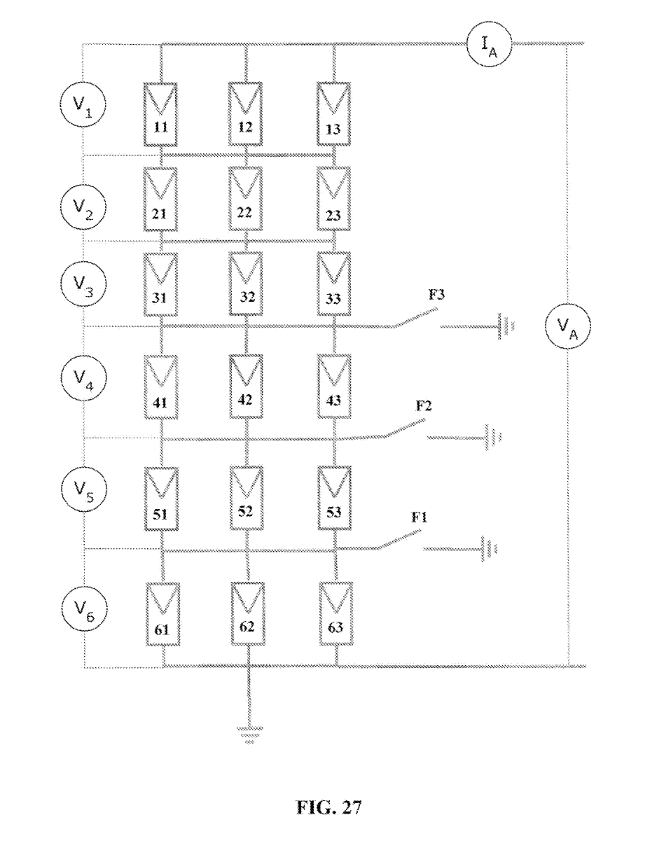

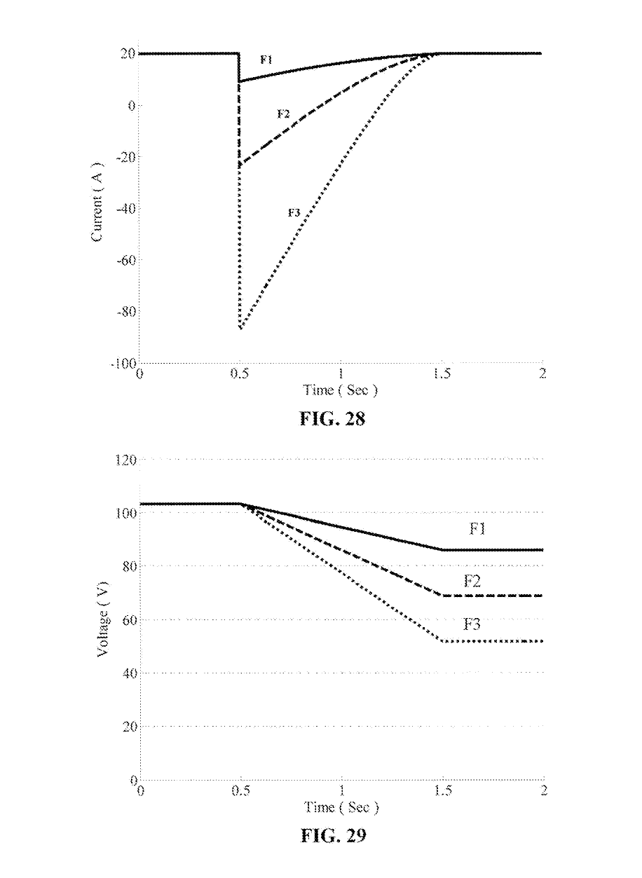

Referring now to FIG. 27, after detecting the occurrence of a fault condition, the location of fault can be found using the voltage sensors (V1, . . . , V6) for the parallel circuits. FIG. 27 shows a PV structure connected in TCT. This structure is subjected to three ground faults F1, F2 and F3 individually. FIG. 28 and FIG. 29 shows the time response of the output voltage and current respectively of the PV structure as determined by the voltage sensor and current sensor. The initial value of the PV structure voltage and current is determined by the Maximum Power Point Tracker (MPPT). During a fault, the current value shows a transient wherein the current changes nearly, instantaneously to a lower value. The voltage value changes to a lower value with a slower rate due to the slow response of the MPPT. This difference in response time between current and voltage may create back-feed currents as in F2 and F3.

The current wave form may be analyzed to indicate the occurrence of a fault. For example, F1 represents a ground fault which is a short circuit on the bottom PV element. The same response could be obtained by shorting any other PV elements in a line to line fault. The same is applied to F2 and F3, wherein the same response could be found by ground fault or by line to line fault of any two or three elements respectively. The current transient has information about the occurrence of a fault (high security) but it does not have enough information about the location of the fault, which is a requirement for high discrimination.

The location of the fault can be found by measuring the voltage across each row. The row which has the lowest voltage is the faulted row. It is important to note that the measurement of the row voltages alone without the array current transients gives high discrimination but low security, since the voltage measurement can indicate a low voltage value due to partial shading not due to fault.

For open circuit and performance reduction faults detection, the mismatch reduction engine implements a sorting algorithm, described below, that sorts the PV elements in descending (or ascending) order according to their irradiance levels, which is proportional to the generated power. This sorting could be stored on the storage medium for a preconfigured amount of time and the elements at the end of the sorting can be checked for faults by a maintenance crew.

First, irradiance levels can be estimated for the purpose of sorting by the following equations:

$$\begin{matrix} {IRR}_{q} = \frac{G}{{I}_{sc}} [ {I}_{0} ( e \text{?} - 1 ) + \text{?} + \text{?} ] ∀ q & ( 14 ) \\ {IRR}_{i} = \frac{G}{{I}_{sc}} [ {n}_{F} {I}_{0} ( e \text{?} - 1 ) + {n}_{F} \text{?} + \text{?} ] ∀ i \\ \text{?} \text{indicates text missing or illegible when filed} & ( 15 )\end{matrix}$$

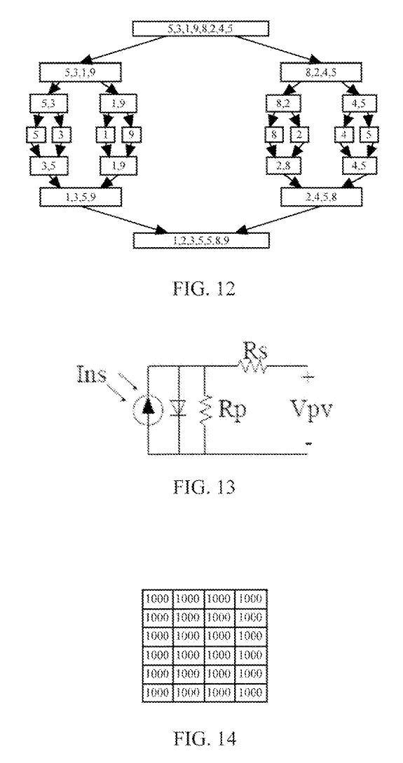

There are several sorting algorithms known to persons skilled in the art that could be used, including bubble sort, insertion sort and merge sort. Preferably, the mismatch reduction engine implements a merge sort since it is relatively fast in computation among these algorithms and is therefore more suitable for real-time applications. FIG. 12 illustrates an example of a merge sort, which recursively divides an unsorted list into two sub-lists of about half the list's size, then sorts each sub-list recursively and merges the sorted sub-lists to provide a sorted list.

The sorted list can be stored on the storage medium. Subsequently, the mismatch reduction engine may compare a newly sorted list to the previously sorted list. If the sorted list has not changed since the last sort, then the PV structure is already optimally configured. Otherwise, some reconfiguration of the PV structure may be required.

If the sorted list has changed, the mismatch reduction engine can determine which signals must be switched by implementing a switching signal minimization algorithm. The PV elements are connected in the PV structure in a TCT connection. Since each PV element in a TCT connection is part of one and only one parallel circuit, changing the switches of a particular PV element is not required if either the location of the PV element in the sorted list has not changed since the previously sorted list, or the location has changed but the PV element would still be connected in the same parallel circuit. Thus, the mismatch reduction engine checks the previous and the new positions for each PV element. If a PV element is to be connected into a different parallel circuit, then the element will be switched, otherwise, no change needs to be made.

The mismatch reduction engine can then configure the PV structure in accordance with the method described in association with FIG. 7, above.

Referring now to FIG. 13, the mismatch reduction achievable by the mismatch reduction engine can be verified by modelling a PV structure and providing examples of mismatch for the PV structure. In these examples, mismatch is caused by a partial shading condition.

An example PV structure may comprise a plurality of PV cells, each modelled by a single diode equivalent circuit as shown, where Ins refers to insolation. Correspondingly, PV modules can be modelled by the connection of a plurality of PV cells, PV arrays and farms can be, modelled by the connection of a plurality of PV modules, etc.

The reduction in partial shading loss can be observed by modelling the PV structure as, for example, a 6×4 array of PV cells and connecting the array in each of series-parallel connection without bypass diodes (SP), series-parallel connection with bypass diodes (SPWD), total-cross-tied connection (TCT) and the connection determined by the mismatch reduction engine (also referred to herein as smart PV array or SPA). A comparison can be made for these PV structures of array maximum power point (MPP), modules' generated powers at array's MPP, array's P-V characteristics, Performance Ratio (PR) and MI. PR and MI provide an indication of partial shading loss in the array.

Referring now to FIG. 14, a first example is a benchmark comparing SP, SPWD, TCT and SPA at no partial shading, where the numbers indicate irradiance levels of the PV elements at their physical locations in W/m².

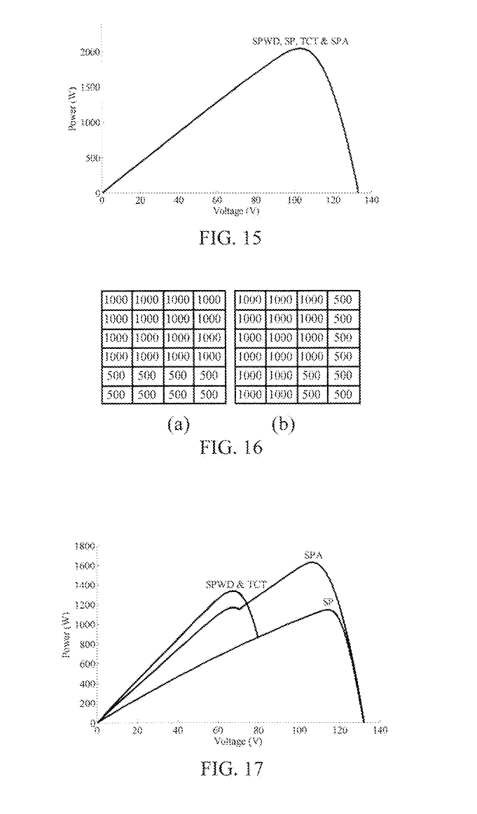

Referring now to Table 1 and FIG. 15, the PR is unity for all PV structures and all are working at their MPPs. Uniform irradiance levels for similar PV elements will allow them to generate equal powers at the same operating voltages and currents. If the operating voltages and currents of all PV elements are adjusted at their MPPs, maximum available power will be obtained. Since all PV elements are similar, this can be achieved by a single MPPT at the PV structure terminals. This MPPT will give the PV structure MPP under these irradiance levels. This means that if the PV structure voltage is adjusted to work at the MPP, then the PV elements' voltages will work at their MPPs. Also, all the PV elements are operating at their MPPs. The MPP for the PV structure is 2,040 W and for the PV element is 85 W. It can therefore be seen that under no partial shading, a PV structure having SPA connections operates equally well as that having SP, SPWD and TCT connections.

TABLE 1

| | | | | | PV | | | Power |
|---|---|---|---|---|---|---|---|---|
| | PV elements' | | | | structure | | | change w.r.t |
| | powers (W) | | | | MPP (W) | PR | MI | SP (%) |
| SP, | 85 | 85 | 85 | 85 | 2040 | 1.00 | 0.00 | — |
| SPWD, TCT | 85 | 85 | 85 | 85 | | | | |
| & SPA | 85 | 85 | 85 | 85 | | | | |
| | 85 | 85 | 85 | 85 | | | | |
| | 85 | 85 | 85 | 85 | | | | |
| | 85 | 85 | 85 | 85 | | | | |

Referring now to FIG. 16a, a second example shows a partial shading condition where the bottom two rows of the PV structure are partially shaded. In FIG. 16b, the PV elements in the bottom two rows have been reconfigured to be distributed among the parallel circuits of the PV structure by the mismatch reduction engine.

Referring to Table 2 and FIG. 17, a comparison is shown between SP, SPWD, TCT and SPA under the partial shading condition. The maximum available power will be available when all PV elements operate at their MPPs, which are 85 W and 42.5 W for the 1000 W/m² and 500 W/m² PV elements, respectively. The PV elements in the SP PV structure are not operating at their MPPs, since the PV structure MPP does not match the PV elements' MPPs, which reduces its PR. In SPWD and TCT the 1000 W/m² PV elements are operating at their MPPs while the 500 W/m² PV elements are turned off although they can generate power. Turing off of these PV elements reduces the PR, which can be solved by using SPA. SPA reduces MI thus increasing PR; moreover SPA makes the P-V characteristics smoother and easier for MPPT.

TABLE 2

| | | | | | Array | | | Power |
|---|---|---|---|---|---|---|---|---|
| | Modules' | | | | MPP | | | change w.r.t |
| | powers (W) | | | | (W) | PR | MI | SP (%) |
| SP | 51.5 | 51.5 | 51.5 | 51.5 | 1148 | 0.675 | — | — |
| | 51.5 | 51.5 | 51.5 | 51.5 | | | | |
| | 51.5 | 51.5 | 51.5 | 51.5 | | | | |
| | 51.5 | 51.5 | 51.5 | 51.5 | | | | |
| | 40.4 | 40.4 | 40.4 | 40.4 | | | | |
| | 40.4 | 40.4 | 40.4 | 40.4 | | | | |
| SPWD | 85 | 85 | 85 | 85 | 1338 | 0.787 | — | 16.6 |
| | 85 | 85 | 85 | 85 | | | | |
| | 85 | 85 | 85 | 85 | | | | |
| | 85 | 85 | 85 | 85 | | | | |
| | −3.1 | −3.1 | −3.1 | −3.1 | | | | |
| | −3.1 | −3.1 | −3.1 | −3.1 | | | | |
| TCT | 85 | 85 | 85 | 85 | 1338 | 0.787 | 64 | 16.6 |
| | 85 | 85 | 85 | 85 | | | | |
| | 85 | 85 | 85 | 85 | | | | |
| | 85 | 85 | 85 | 85 | | | | |
| | −3.1 | −3.1 | −3.1 | −3.1 | | | | |
| | −3.1 | −3.1 | −3.1 | −3.1 | | | | |
| SPA | 80.8 | 80.8 | 80.8 | 41.2 | 1630 | 0.959 | 4 | 42 |
| | 80.8 | 80.8 | 80.8 | 41.2 | | | | |
| | 80.8 | 80.8 | 80.8 | 41.2 | | | | |
| | 80.8 | 80.8 | 80.8 | 41.2 | | | | |
| | 83.1 | 83.1 | 40.6 | 40.6 | | | | |
| | 83.1 | 83.1 | 40.6 | 40.6 | | | | |

Referring now to FIG. 18a, a third example shows a partial shading condition where the lower left quadrant of the PV structure is partially shaded. In FIG. 18b, the shaded PV elements have been reconfigured to be distributed among the parallel circuits of the PV structure by the mismatch reduction engine.

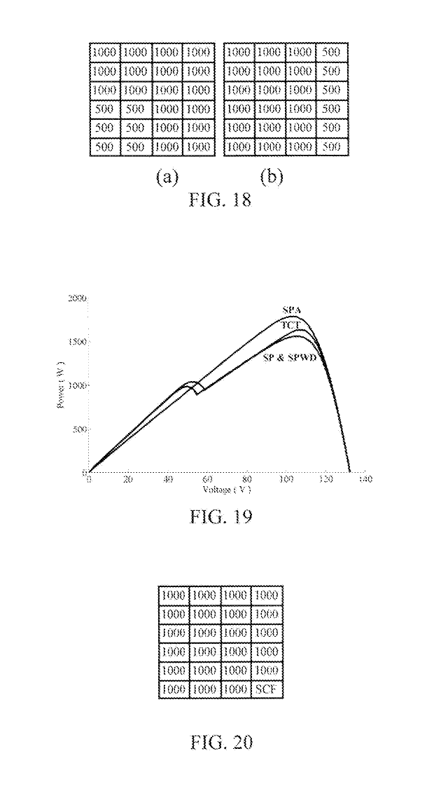

Referring to Table 3 and FIG. 19, a comparison is shown between SP, SPWD, TCT and SPA under the partial shading condition. SP and SPWD are similar to each other, since bypass diodes are not turned on (bypass diodes may not turn on for low mismatch). TCT has a better PR than SP and SPWD due to lower mismatch. SPA will generate more power than TCT because it has lower mismatch (zero). SPA also provides smoother P-V characteristics than TCT.

TABLE 3

| | | | | | Array | | | Power |
|---|---|---|---|---|---|---|---|---|
| | Modules' | | | | MPP | | | change w.r.t |
| | powers (W) | | | | (W) | PR | MI | SP (%) |
| SP& | 52.1 | 52.1 | 84.9 | 84.9 | 1557 | 0.872 | — | — |
| SPWD | 52.1 | 52.1 | 84.9 | 84.9 | | | | |
| | 52.1 | 52.1 | 84.9 | 84.9 | | | | |
| | 37.4 | 37.4 | 84.9 | 84.9 | | | | |
| | 37.4 | 37.4 | 84.9 | 84.9 | | | | |
| | 37.4 | 37.4 | 84.9 | 84.9 | | | | |
| TCT | 73.1 | 73.1 | 73.1 | 73.1 | 1630 | 0.913 | 18 | 4.7 |
| | 73.1 | 73.1 | 73.1 | 73.1 | | | | |
| | 73.1 | 73.1 | 73.1 | 73.1 | | | | |
| | 41.2 | 41.2 | 84.1 | 84.1 | | | | |
| | 41.2 | 41.2 | 84.1 | 84.1 | | | | |
| | 41.2 | 41.2 | 84.1 | 84.1 | | | | |
| SPA | 85 | 85 | 85 | 42.5 | 1786 | 1.000 | 0.00 | 14.7 |
| | 85 | 85 | 85 | 42.5 | | | | |
| | 85 | 85 | 85 | 42.5 | | | | |
| | 85 | 85 | 85 | 42.5 | | | | |
| | 85 | 85 | 85 | 42.5 | | | | |
| | 85 | 85 | 85 | 42.5 | | | | |

Referring now to FIG. 20, a fourth example shows a one short circuited PV element, where SCF means Short Circuit Fault. In SP and TCT arrays, the faulted PV element is not disconnected because there are no fault detection and isolation capabilities. The mismatch reduction engine of the SPA, however, will detect the fault and disconnect the faulty PV element from the PV structure.

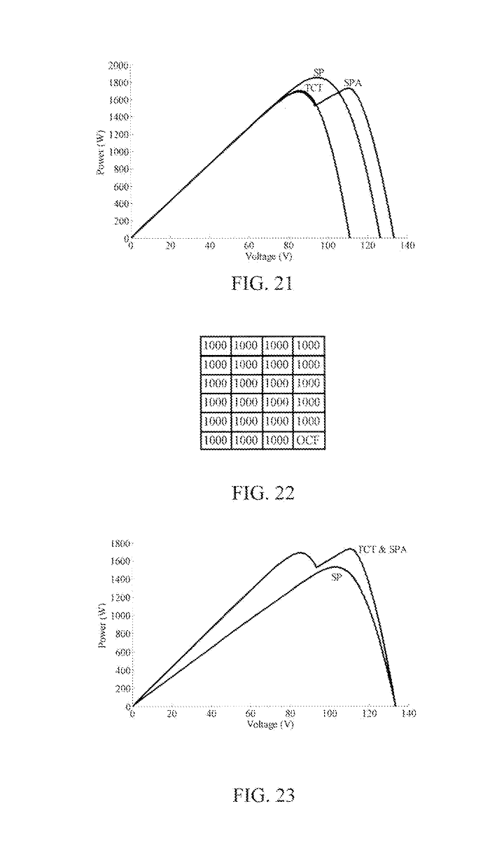

Referring to Table 4 and FIG. 21, a comparison is shown between SP, SPWD, TCT and SPA under the fault condition. During the fault, SP will have five PV element columns. A short circuit fault of one element in TCT will short an entire row thus reducing the array size to 5×4. SPA will disconnect the faulted module, thus generating more power than TCT.

TABLE 4

| | | | | | | | Power |
|---|---|---|---|---|---|---|---|
| | Modules' | | | | Array MPP | | change w.r.t |
| | powers (W) | | | | (W) | PR | SP (%) |
| SP& | 81.7 | 81.7 | 81.7 | 77.1 | 1855 | 0.949 | 1855 |
| SPWD | 81.7 | 81.7 | 81.7 | 77.1 | | | |
| | 81.7 | 81.7 | 81.7 | 77.1 | | | |
| | 81.7 | 81.7 | 81.7 | 77.1 | | | |
| | 81.7 | 81.7 | 81.7 | 77.1 | | | |
| | 81.7 | 81.7 | 81.7 | 0 | | | |
| TCT | 85.1 | 85.1 | 85.1 | 85.1 | 1703 | 0.871 | 1703 |
| | 85.1 | 85.1 | 85.1 | 85.1 | | | |
| | 85.1 | 85.1 | 85.1 | 85.1 | | | |
| | 85.1 | 85.1 | 85.1 | 85.1 | | | |
| | 85.1 | 85.1 | 85.1 | 85.1 | | | |
| | 0 | 0 | 0 | 0 | | | |
| SPA | 74.9 | 74.9 | 74.9 | 74.9 | 1734 | 0.887 | 1734 |
| | 74.9 | 74.9 | 74.9 | 74.9 | | | |
| | 74.9 | 74.9 | 74.9 | 74.9 | | | |
| | 74.9 | 74.9 | 74.9 | 74.9 | | | |
| | 74.9 | 74.9 | 74.9 | 74.9 | | | |
| | 78.2 | 78.2 | 78.2 | 0 | | | |

Referring now to FIG. 22, a fifth example shows a one open circuited PV element, where OCF means Open Circuit Fault. It should be noted that the OCF can be located at any PV element giving the same result.

Referring to Table 5 and FIG. 23, a comparison is shown between SP, SPWD, TCT and SPA under the fault condition. For SP, a complete column will be disabled and the structure will be equivalent to a 6×3 array. TCT and SPA will give similar generated powers.

TABLE 5

| | | | | | | | Power |
|---|---|---|---|---|---|---|---|
| | Modules' | | | | Array MPP | | change w.r.t |
| | powers (W) | | | | (W) | PR | SP (%) |
| SP& | 85.1 | 85.1 | 85.1 | 0 | 1532 | 0.784 | 1532 |
| SPWD | 85.1 | 85.1 | 85.1 | 0 | | | |
| | 85.1 | 85.1 | 85.1 | 0 | | | |
| | 85.1 | 85.1 | 85.1 | 0 | | | |
| | 85.1 | 85.1 | 85.1 | 0 | | | |
| | 85.1 | 85.1 | 85.1 | 0 | | | |
| TCT | 74.9 | 74.9 | 74.9 | 74.9 | 1734 | 0.887 | 1734 |
| | 74.9 | 74.9 | 74.9 | 74.9 | | | |
| | 74.9 | 74.9 | 74.9 | 74.9 | | | |
| | 74.9 | 74.9 | 74.9 | 74.9 | | | |
| | 74.9 | 74.9 | 74.9 | 74.9 | | | |
| | 78.2 | 78.2 | 78.2 | 0 | | | |
| SPA | 74.9 | 74.9 | 74.9 | 74.9 | 1734 | 0.887 | 1734 |
| | 74.9 | 74.9 | 74.9 | 74.9 | | | |
| | 74.9 | 74.9 | 74.9 | 74.9 | | | |
| | 74.9 | 74.9 | 74.9 | 74.9 | | | |
| | 74.9 | 74.9 | 74.9 | 74.9 | | | |
| | 78.2 | 78.2 | 78.2 | 0 | | | |

It can be seen that a PV structure having SPA connections provides substantially beneficial results that having SP and TCT connections in most cases.

Although the invention has been described with reference to certain specific embodiments, various modifications thereof will be apparent to those skilled in the art without departing from the spirit and scope of the invention as outlined in the claims appended hereto. The entire disclosures of all references recited above are incorporated herein by reference.

What is claimed is:

1. A photovoltaic structure characterized by a plurality of photovoltaic elements, said photovoltaic elements selectively electrically connectable to one another based on sorting said photovoltaic elements by a respective irradiance level.

2. The photovoltaic structure of claim 1, characterized in that said photovoltaic structure comprises a plurality of parallel circuits, each of said parallel circuits capable of comprising one or more of said photovoltaic elements, wherein said photovoltaic elements are selectively electrically connectable to one another by:
(a) establishing an order for said plurality of parallel circuits,
(b) establishing a serpentine arrangement by connecting each one of a first set of said sorted photovoltaic elements to one of said parallel circuits in accordance with said order, and connecting each one of a second set of said sorted photovoltaic elements to said parallel circuits in accordance with a reverse order to said order; and
(c) repeating said serpentine arrangement for the remaining sorted photovoltaic elements.

3. The photovoltaic structure of claim 2, characterized in that said photovoltaic structure further comprises a plurality of non-reconfigurable photovoltaic elements electrically connected to said plurality of parallel circuits.

4. The photovoltaic structure of claim 3, characterized in that said non-reconfigurable photovoltaic elements are sorted based on a respective irradiance level to establish said order.

5. The photovoltaic structure of claim 2, characterized in that said parallel circuits are connected in series.

6. The photovoltaic structure of claim 1, characterized in that said selective electrical connection reduces partial shading loss of said photovoltaic structure.

7. The photovoltaic structure of claim 1, characterized in that said photovoltaic elements are photovoltaic cells, photovoltaic modules, photovoltaic panels, photovoltaic arrays, photovoltaic farm fields, photovoltaic farms, or any combination thereof.

8. The photovoltaic structure of claim 1, characterized in that said photovoltaic structure further comprises a plurality of irradiance level sensors for determining said irradiance levels.

9. The photovoltaic structure of claim 1, characterized in that said photovoltaic structure further comprises a plurality of voltage sensors and current sensors for determining said irradiance levels.

10. The photovoltaic structure of claim 1, characterized in that said photovoltaic structure further comprises a plurality of switches for said selective electrical connections.

11. The photovoltaic structure of claim 2, characterized in that at least two of said parallel circuits comprise unequal numbers of said photovoltaic elements.

12. A method of electrically connecting a plurality of photovoltaic elements in a photovoltaic structure, said method characterized by:
(a) determining irradiance levels for said photovoltaic elements;
(b) sorting said photovoltaic elements by said irradiance levels; and
(c) electrically connecting said photovoltaic elements to one another based on said sorted irradiance levels.

13. The method of claim 12, wherein said photovoltaic structure comprises a plurality of parallel circuits, each of said parallel circuits capable of comprising one or more of said photovoltaic elements, characterized in that said photovoltaic elements are selectively electrically connectable to one another by:
(a) establishing an order for said plurality of parallel circuits,
(b) establishing a serpentine arrangement by connecting each one of a first set of said sorted photovoltaic elements to one of said parallel circuits in accordance with said order, and connecting each one of a second set of said sorted photovoltaic elements to said parallel circuits in accordance with a reverse order to said order; and
(c) repeating said serpentine arrangement for the remaining sorted photovoltaic elements.

14. The method of claim 12, further characterized by connecting said parallel circuits in series.

15. The method of claim 12, characterized in that said selective electrical connection reduces partial shading loss of said photovoltaic structure.

16. The method of claim 12, further characterized by detecting faults in said photovoltaic elements and electrically disconnecting said photovoltaic elements from said photovoltaic structure.

17. The method of claim 12, further characterized by:
(a) determining a second set of irradiance levels;
(b) resorting said photovoltaic elements by said second set of irradiance levels; and
(c) electrically reconnecting said photovoltaic elements only if the order of said resorted photovoltaic elements is different than the order of said sorted photovoltaic elements.

18. The method of claim 12, further characterized by:
(a) determining a second set of irradiance levels;
(b) resorting said photovoltaic elements by said second set of irradiance levels;
(c) determining whether any of said photovoltaic elements do not need to be electrically reconnected based on said resorting; and
(d) electrically reconnecting remaining ones of said photovoltaic elements to one another based on said resorting.

19. The method of claim 13, characterized in that at least two of said parallel circuits comprise unequal numbers of said photovoltaic elements.

20. A photovoltaic structure characterized by a plurality of photovoltaic elements, said photovoltaic elements selectively electrically connectable to one another based on determining a minimum mismatch between said parallel circuit.

21. A photovoltaic structure characterized by a plurality of photovoltaic elements, said photovoltaic elements selectively electrically connectable to one another based on determining a maximum output power of said photovoltaic structure.
